(19) United States
(12) Patent Application Publication
(10) Pub. No.: US 2026/0293670 A1
(43) Pub. Date: Sep. 24, 2026

(54) HEAT-DISSIPATING SEMICONDUCTOR PACKAGE WITH EMBEDDED HEAT-CONDUCTING MEMBER, METHOD FOR MANUFACTURING THE SAME, AND INDUCTION-HEATING SOLDERING DEVICE USED IN MANUFACTURING THE SAME

(71) Applicant: BS TECHNICS CO., LTD., Gyeonggi-do (KR)

(72) Inventors: Jun Sik KIM, Gyeonggi-do (KR); Young Do KIM, Gyeonggi-do (KR); Jung Sik CHOI, Gyeonggi-do (KR); Tae Kyoung JUNG, Gyeonggi-do (KR); In Ho PARK, Incheon (KR)

(21) Appl. No.: 18/873,925

(22) PCT Filed: Jun. 15, 2023
(86) PCT No.: PCT/KR2023/008232

§ 371 Date: Dec. 11, 2024

(30) Foreign Application Priority Data
Jun. 21, 2022 (KR) 10-2022-0075853

(51) Int. Cl. H10W 40/20; H10W 40/00; H10W 40/25; H10W 72/00; H10W 72/30; H10W 74/10; H10W 90/00

(52) U.S. Cl. CPC H10W 40/242; H10W 40/03; H10W 40/255; H10W 72/07335; H10W 72/07336; H10W 74/141; H10W 90/724; H10W 90/736; H10W 72/322; H10W 72/352

(57) ABSTRACT

The present invention relates to a heat-dissipating semiconductor package with an embedded heat-conducting member and a method for manufacturing the same, wherein a heat-conducting member, which is a heat-dissipating means dissipating heat generated inside the semiconductor package to the outside, is implemented by being embedded in a molding part configuring the outer shape of the semiconductor package so that optimal heat conduction can be implemented within the minimum thickness of the molding part of the semiconductor package.

### TECHNICAL FIELD

The present invention relates to a semiconductor package, and more particularly, to a semiconductor package including a heat-dissipating technology using a heat-conducting member and manufacturing the same.

### BACKGROUND ART

A semiconductor package is formed by mounting a semiconductor chip on a board and molding a single module of a structure in which the semiconductor chip and a lead frame are connected by using a bonding flip chip or a bonding wire, and the like with a thermosetting material such as epoxy molding compound (EMC) to form a package body (molding part).

As illustrated in FIG. 8, the semiconductor package is manufactured through eight representative processes. First, very high-purity single-crystal silicon (SiO₂) is used for a wafer, which becomes a base plate of a direct circuit, and after the the single-crystal silicon manufactured in the form of an ingot, the ingot is cut to be used as the wafer. After the oxidation process on this wafer, photo processes (photosensitization, exposure, and development) are performed, and then an etching process is performed, and a circuit pattern is implemented through thin film vapor-deposition and metal wiring processes. Depending on the stacked structure, these processes are repeated to implement a multilayer circuit. After that, an EDS process is performed to check whether the individual semiconductor chips have reached a desired quality level through electrical characteristic inspection. When a certain quality is checked to be reached through the EDS process, paths are created so that the semiconductor chip can exchange signals with the outside, a packaging process is performed by injecting and hardening an epoxy resin on the semiconductor chip to protect the semiconductor chip from various external environments.

At this time, the product finally created through the packaging process is called a semiconductor package.

Early, semiconductor packages were called small-scale integration (SSI) containing only a few transistors. Later, medium-scale integration (MSI) containing hundreds of transistors were developed. And then, large-scale integration (LSI) containing tens of thousands of transistors were developed. Currently, very large scale integration (VLSI) containing a large-scale semiconductor chip including 10,000 to 1,000,000 transistors has been developed.

After that, in ultra large scale integration (ULSI) reflecting the continued increase in complexity, integrated circuits such as SOC (System-On-a-Chip) containing semiconductor chips with ultra-large integration containing over a million transistors and including all components required for a computer or other system on a single chip have been developed and manufactured.

In this way, as semiconductor technology becomes more advanced and the speed of semiconductor chips increases and their functions increase, a problem of heat generation becomes more serious, and a heat dissipation function of the semiconductor packages becomes very important.

A heat dissipation technology for semiconductor packages in the related art is a technology that directly attaches a heat sink to a surface of the package body (hereinafter, the molding part). In a semiconductor package in the related art, heat generated from the semiconductor chip is transferred to the heat sink through the molding part made of plastic and dissipated to the outside.

However, the plastic material configuring the molding part not only has low thermal conductivity, but also, due to the thickness of the molding part itself, the heat dissipation through the heat sink attached to the molding part is not large.

As illustrated in FIG. 1, another heat dissipation technology for the semiconductor packages is a technology of attaching a sheet (TIM sheet) containing a thermal interface material (TIM) to the molding part. However, since this TIM sheet is also attached to a surface of the molding part, the heat dissipation is still not large. In addition, the TIM sheet is attached to the molding part through its own adhesive force or an adhesive, but since the adhesive force is weakened after a long period of time, the TIM sheet easily falls off from the molding part, which causes a problem in that a heat conduction effect is reduced.

### SUMMARY OF INVENTION

### Technical Problem

The present invention has been made in order to solve the above-described problems of the related art, and an object of the present invention is to provide a semiconductor package and a method for manufacturing the same, which can implement improved performance of a semiconductor chip by preventing malfunction and damage of the semiconductor chip due to overheating by having a heat dissipation structure of the semiconductor package for effectively dissipating heat generated from the semiconductor chip.

### Solution to Problem

To solve the above-described object of the present invention, a heat-dissipating semiconductor package with an embedded heat-conducting member includes: a board; a semiconductor chip mounted on the board; a molding part surrounding a side surface of the semiconductor chip on the board; and the heat-conducting member embedded in the molding part and dissipating heat generated from the semiconductor chip to an outside of the molding part.

Herein, an engraved portion is formed with a predetermined thickness on at least one side of the molding part, and the heat-conducting member includes a heat-conducting sheet bonded to an inside of the engraved portion and dissipating heat generated from the semiconductor chip to the outside.

And, an uneven surface with a plurality of uneven portions is formed on the bottom surface of the engraved portion, and the heat-conducting member further includes a metal layer vapor-deposition-formed on the uneven surface and solder paste applied on the metal layer, so that the heat-conducting sheet is soldering-bonded to the metal layer.

In addition, to solve the above-described object of the present invention, a heat-dissipating semiconductor package includes: providing a semiconductor package in which a packaging process of a semiconductor chip is completed; forming an engraved portion with an uneven surface formed on at least one surface of a molding part configuring an outer shape of the semiconductor package by laser processing; vapor-depositing a metal layer on the concave surface by plating; dispensing solder paste on the metal layer; mounting a heat-conducting sheet on the solder paste; and melting the solder paste by heating the solder paste.

In addition, to solve the above-described object of the present invention, an induction-heating soldering device that induction-heats a metal layer vapor-deposited on a surface of a molding part of a semiconductor package to solder a heat-conducting sheet to the metal layer, includes: an induction-heating coil electrically connected to a high-frequency power supply unit to induce an electromagnetic field; a magnetic core located inside the induction-heating coil to concentrate a magnetic flux onto the heat-conducting sheet; and a coil bobbin with the induction-heating coil disposed on an outer surface and the magnetic core installed in a center, wherein the coil bobbin has an open upper portion so that cooling air flows into the coil bobbin through the upper opening, and a plurality of through-holes with holes are formed on a side of the coil bobbin so that the cooling air passes through the magnetic core and is discharged to the outside through the through-holes.

### Advantageous Effects of Invention

The heat-conducting member embedded in the heat-dissipating semiconductor package according to the present invention configured as described above and the manufacturing method thereof have the following advantages.

First, since the heat-conducting member that dissipates heat generated from the inside of the semiconductor package to the outside is embedded within a thickness of the molding part configuring the outer shape of the semiconductor package, there is an advantage that optimal heat conduction can be implemented within a minimum thickness of the molding part of the semiconductor package.

Second, since the heat inside the semiconductor package can be efficiently dissipated without an additional heat-dissipating member added to the outside, there is an advantage that high capacity, miniaturization, and high reliability can be implemented.

Third, since the heat-conducting member is embedded in a surface of the molding part, the heat-conducting member can be installed on upper and/or side surfaces of the molding part, so that three-dimensional heat dissipation and heat conduction can be implemented, and there is also an advantage that the heat-dissipating portion can be actively responded depending on the spatial environment in which the semiconductor package is installed.

Fourth, by directly implementing the heating-conducting member in the semiconductor package in which the semiconductor packaging process is completed, a layout design can be done as a continuous process (inline process) after a packaging process, which is very advantageous for mass production.

Fifth, since the heating-conducting member is implemented as a porous engraved surface (uneven surface) on the surface of the molding part, a heat dissipation surface area is greatly expanded, which is advantageous of being able to quickly dissipate a large amount of heat.

Sixth, it also has the advantage of being able to universally respond to various semiconductor package implementation methods such as wire bonding, flip chip bonding, and through silicon via (TSV) and enhancing the heat dissipation performance in the fan-out wafer level package, which is the main package type in the future.

### BRIEF DESCRIPTION OF DRAWINGS

FIG. 1 is a photograph of a state in which a TIM sheet is attached to a semiconductor package in the related art.

FIG. 2 is a schematic diagram illustrating a cross-sectional view of a heat-dissipating semiconductor package according to an embodiment of the present invention.

FIG. 3 is a photograph of an actual product in which a heat-conducting member is directly implemented in the heat-dissipating semiconductor package according to the embodiment of the present invention.

FIG. 4 is a diagram illustrating an example of a usage state of the heat-dissipating semiconductor package according to the embodiment of the present invention.

FIG. 5 is a flowchart illustrating a sequence of processes for manufacturing the heat-dissipating semiconductor package according to the embodiment of the present invention.

FIGS. 6, 7, and 8 are conceptual diagrams illustrating a sequence of processes for manufacturing the heat-dissipating semiconductor package according to the embodiment of the present invention.

FIG. 9 is a diagram illustrating a sequence of processes for manufacturing the heat-dissipating semiconductor package according to the embodiment of the present invention with an actual product.

FIG. 10 is a conceptual diagram illustrating a continuous in-line process of eight processes for manufacturing a semiconductor package in the related art and a process for manufacturing the heat-dissipating semiconductor package according to the embodiment of the present invention.

FIG. 11 is a conceptual diagram illustrating a side cooling air discharge type in an induction-heating unit applied to the heat-dissipating semiconductor package according to the embodiment of the present invention.

FIG. 12 is a conceptual diagram illustrating an upper cooling air discharge type in the induction-heating unit applied to the heat-dissipating semiconductor package according to the embodiment of the present invention.

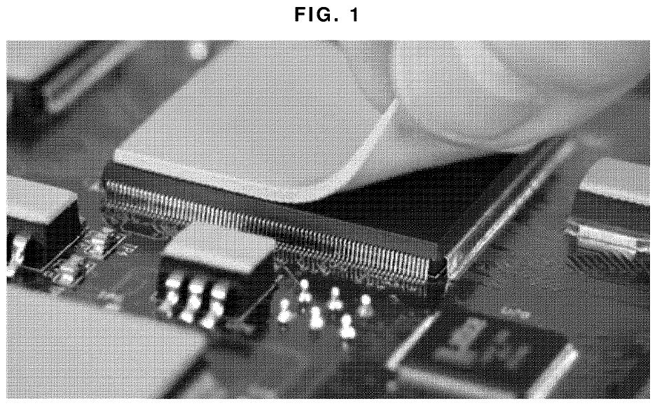

### DESCRIPTION OF EMBODIMENTS

### Best Mode for Carrying out the Invention

A heat-dissipating semiconductor package according to the present invention includes a board, a semiconductor chip mounted on the board, a molding part surrounding a side surface of the semiconductor chip on the board, and a heat-conducting member embedded in the molding part and dissipating heat generated from the semiconductor chip to an outside of the molding part.

### Mode for Carrying out the Invention

The present invention can be modified in various ways and has various embodiments, and specific embodiments are illustrated in the drawings and described in detail in the detailed description. However, the present invention does not intend to be limited to specific embodiments, and it should be understood that the present invention includes all modifications, equivalents, or substitutes included in the spirit and technical scope of the present invention. In describing the present invention, if it is determined that a specific description of a related known technology may obscure the spirit of the present invention, the detailed description thereof will be omitted.

The core technical idea of the present invention is to implement a heat-dissipating means (hereinafter, heat-conducting member) that dissipates heat generated inside a semiconductor package to the outside by being embedded in a molding part configuring the outer shape of the semiconductor package, and thus, it is advantageous to implement optimal heat conduction within the minimum thickness of the molding part of the semiconductor package.

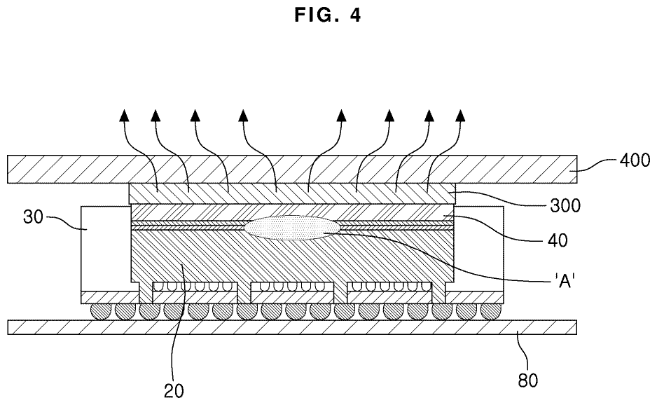

To this end, the present invention forms a concave engraved portion with a certain thickness in the molding part of the semiconductor package at the most intense heat generation area (hot spot: ‘A’ in FIG. 4), vapor-deposits a metal layer on the engraved portion, and after that, bonds the heat-conducting sheet to the metal layer through a soldering process.

Hereinafter, an embodiment of a heat-dissipating semiconductor package in which a heat-conducting member according to the present invention is embedded will be described in detail with reference to the attached drawings.

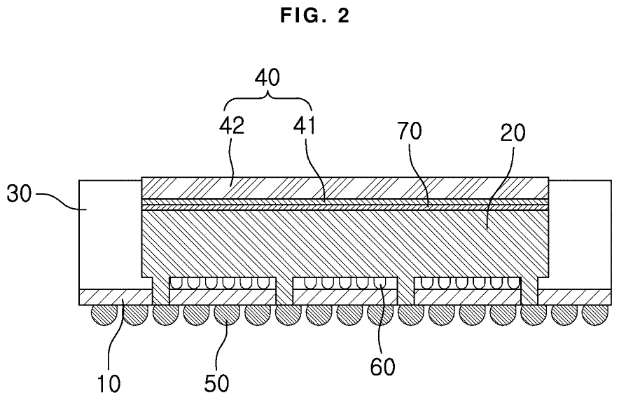

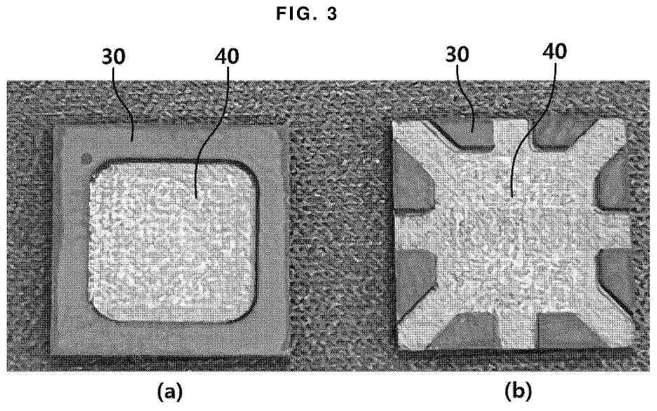

FIG. 2 is a schematic cross-sectional view of the heat-dissipating semiconductor package according to the embodiment of the present invention, FIG. 3 is a photograph of an actual product in which a heat-conducting member is directly implemented in the heat-dissipating semiconductor package according to the embodiment of the present invention, and FIG. 4 is a diagram illustrating an example of a usage state of the semiconductor package according to the embodiment of the present invention.

Referring to FIGS. 2 and 3, the heat-dissipating semiconductor package in which the heat-conducting member is embedded according to the present invention is configured to include a board 10, a semiconductor chip 20, a molding part 30, a heat-conducting member 40, and a solder ball 50.

The above-mentioned board 10 is, for example, a printed circuit board (PCB board) and the like. One or more semiconductor chips are mounted on one side of the board 10. Meanwhile, the other side (the side opposite to the one side) of the board 10 has a connection structure that can be connected to another PCB board (for example, a motherboard: 80 in FIG. 4). As a connection structure, for example, the solder ball 50, a pin connector and the like can be mentioned.

However, the present invention is not limited to the board type. That is, a lead frame type can be applied instead of the board type. In other words, in terms of the electrical connection method of the semiconductor chip, a method of attaching solder balls to a board and connecting the solder balls to the board may be possible. And a method of connecting the semiconductor chip to a lead frame by using wires may also be possible.

The semiconductor chip 20 may be a semiconductor chip that performs various functions such as a memory, a logic, a microprocessor, an analog device, a digital signal processor, and a System-On-Chip. In addition, the semiconductor chip may be a multi-chip having a structure in which at least two or more semiconductor chips are stacked. For example, at least two or more semiconductor chips may all be the same type of device, and one of the two or more semiconductor chips may be a memory device and the other may be a microcontroller device.

The semiconductor chip 20 illustrated in FIG. 2 is mounted on the board 10 by using a flip-chip bonding method, but the mounting method of the semiconductor chip 20 is not limited thereto. For example, the semiconductor chip may be mounted on the board by using a wire bonding method, or the semiconductor chip may be mounted by using a through silicon via (TSV) method in which a number of semiconductor chips are stacked in multiple layers and connected to each other through via holes.

As illustrated in FIG. 2, when the semiconductor chip 20 is mounted by using a flip-chip bonding method, the semiconductor chip 20 may be connected to the board 10 through bumps 60. Meanwhile, the configuration number ‘70’ not described in FIG. 2 is a protective film for protecting the semiconductor chip. At this time, the protective film 70 has an oxide film, a nitride film, or a film form.

The above-mentioned molding part 30 serves to seal the semiconductor chip 20 to protect the semiconductor chip 20 from hazardous factors of the external environment. The molding part 30 may include an insulating material, for example, a thermosetting resin such as an epoxy resin, a thermoplastic resin such as a polyimide, or a resin containing a reinforcing material such as an inorganic filler, specifically, ABF, FR-4, BT resin and the like In addition, a molding material such as epoxy molding compound (EMC) may be used for the molding part 30. Herein, EMC is a relatively small molecular weight resin capable of being three-dimensionally cured in the presence of a curing agent or catalyst and is a thermosetting plastic with excellent mechanical, electrical insulation, and temperature resistance properties. Of course, in the present invention, the material of the molding part 30 is not limited to the aforementioned materials.

In this way, the molding part 30 performs the roles of mechanical protection, electrical connection, and mechanical connection of the semiconductor chip 20. However, recently, as semiconductor technology has advanced and the speed of products has increased and functions are increased, the heat problem becomes very serious, so that technologies that effectively dissipate heat from the molding part 30 are being incorporated. That is, the molding part 30 protects the semiconductor chip 20 from external mechanical and chemical impacts by wrapping the semiconductor chip 20 with a package material such as EMC resin, physically/electrically connects the semiconductor chip 20 to the system, supplies power for the semiconductor chip 20 to operate, allows the semiconductor chip 20 to input and output signals so as to perform the desired functions, and also serves to dissipate the heat generated during the operation of the semiconductor chip 20.

From the above-described viewpoint, the present invention implements the heat-conducting member (40: heat-dissipating means) that dissipates the heat generated from the semiconductor chip 20 to the outside of the semiconductor package in the molding part 30. That is, the heat-conducting member 40 is implemented within a thickness part of the molding part 30. In the present invention, this is defined and used as a heat-conducting member embedded in the molding part 30.

Hereinafter, the heat-conducting member 40 embedded in the molding part 30 will be described in more detail with reference to FIGS. 2 to 4 and FIGS. 6 to 7.

The above-mentioned heat-conducting member 40 is configured to include a metal layer 41 formed in the molding part 30 and a heat-conducting sheet 42 bonded to the metal layer 41. To this end, an engraved portion 31 on which the metal layer 41 is vapor-deposited is formed on one surface of the molding part 40, and an uneven surface 42 is formed on the bottom surface of the engraved portion 31.

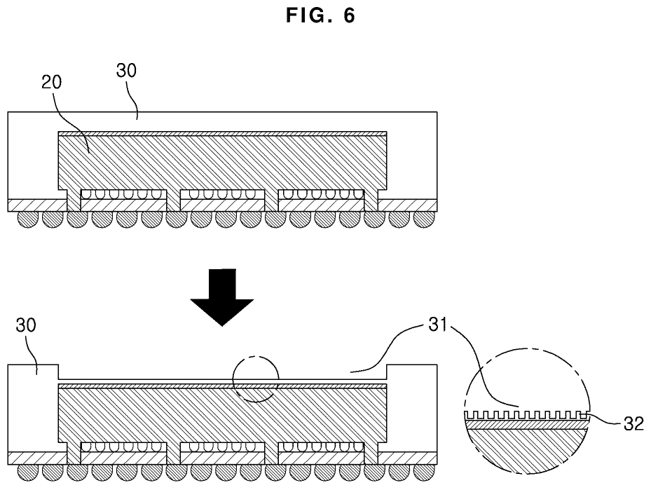

The above-mentioned engraved portion 31 can be formed to have a certain depth in at least one area of the first surface of the molding part. This engraved portion 31 can be formed by removing the molding part 30 to a certain depth through laser processing and the like, which will be described later. For example, as illustrated in FIG. 6, in order to protect the semiconductor chip 20 from the initial thickness of the molding part 30, only the molding part with a thickness of 5 to 10 μm can be left on the semiconductor chip 20 and the remaining portion can be removed to form the engraved portion 31. However, it is not limited thereto, and it is obvious that the depth of the engraved portion 31 can be variously modified depending on the type and size of the semiconductor package or semiconductor chip.

At this time, the engraved portion 31 may have a concave groove shape with a square plane inside while retaining a certain width of an edge on one side of the molding part 30 as illustrated in (a) of FIG. 3, and may also have a concave groove shape that extends radially from the center and vertex of each side of the square plane to the edge of the molding part 30 as illustrated in (b) of FIG. 3. In the latter case, the area of the heat-conducting member 40 can be maximized, so that there is an advantage of a better heat dissipation effect.

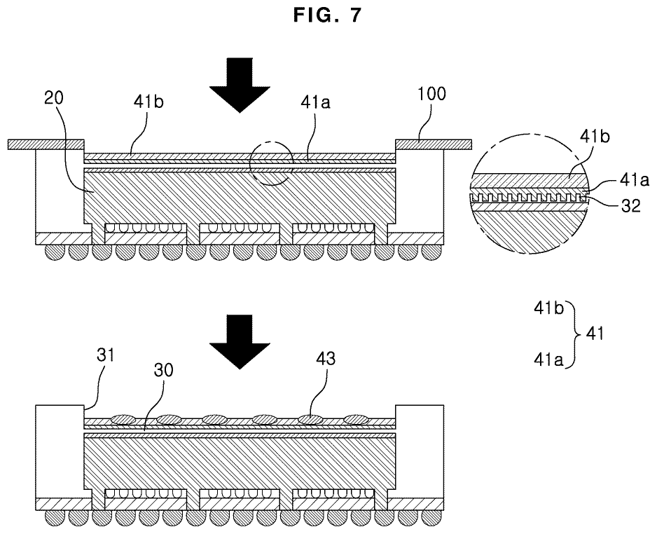

As illustrated in FIGS. 6 and 7, the uneven surface 32 may have an uneven shape in the form of a diagonal or straight line with a periodically repeated convex and concave pattern on the bottom surface of the engraved portion 31 when forming the engraved portion 31 through laser processing and the like However, the present invention is not limited to this and may have various other shapes. Such the uneven surface 32 can increase the bonding strength with the metal layer 41 through anchoring of metal materials in the vapor-deposition process for forming the metal layer 41, and can also increase the heat dissipation effect by expanding the heat dissipation surface area.

As illustrated in FIG. 7, the metal layer 41 is formed on the uneven surface 32 inside the engraved portion 31, and plays a role in vertically transferring heat generated from the semiconductor chip 20, and also plays a role as a medium for soldering the heat-conducting sheet 42 to the molding part 30 made of a resin material. This metal layer 41 has a structure that is plated and vapor-deposited in the engraved area. To elaborate further, the metal layer 41 is formed by a selective plating process inside the engraved portion 31, and can be dry or wet plating depending on the laser processing and the semiconductor package status. A more detailed description of the process of forming the metal layer 41 will be described later.

Herein, the metal layer 41 may be formed of multiple layers. According to various embodiments, the metal layer may include a first metal layer 41a and a second metal layer 41b. Herein, the first metal layer 41a is formed directly on the laser-processed engraved portion 31 and has a role of having a high bonding strength through anchoring to the molding part 30 made of a resin material, and may have an area that is in contact with the semiconductor chip 20, so it is preferable to use a metal material with low diffusion. For example, the first metal layer 41a may include at least one of copper (Cu), nickel (Ni), aluminum (AI), titanium (Ti), and silicon (Si). And the second metal layer 41b has excellent solderability for soldering-bonding with the heat-conducting sheet 420 and serves as a heat-conducting mediating layer after bonding. Therefore, it is preferable to use a metal material that is excellent in soldering and has good heat conductivity for the second metal layer 41b. For example, the second metal layer 41b may include at least one of copper (Cu), nickel (Ni), and gold (Au).

The above-mentioned heat-conducting sheet 42 is bonded to the metal layer 41 in the form of a thin plate made of a heat-conducting material. More specifically, the heat-conducting sheet 42 is bonded to the second metal layer 41b. This heat-conducting sheet 42 is disposed on the outermost side of the engraved portion 31 in the molding part 30 and plays a role in dissipating heat generated from the semiconductor chip 20 to the outside of the semiconductor package.

In addition, as illustrated in FIG. 4, when the heat-dissipating semiconductor package according to the present invention is assembled to the motherboard 70 of an electronic device, it can be connected to a TIM (thermal interface material) sheet 300 and/or an EMI shielding member 400 as an additional heat-dissipating means to effectively dissipate heat to the outside. Herein, the TIM sheet 300 includes a sheet made of a thermal interface material (TIM), and the EMI shielding member 400 is installed around the semiconductor package to block electromagnetic waves.

The heat-conducting sheet 42 may be made of a metal material such as copper or aluminum, a semi-metal material such as silicon, or a carbon-based fiber such as carbon or graphite. Of course, in the present invention, the material of the heat-conducting sheet is not limited to the above-mentioned materials.

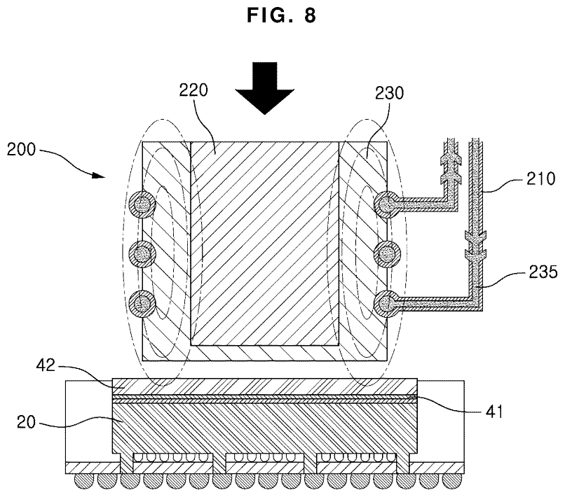

Referring to FIGS. 7 and 8, the heat-conducting sheet 42 may be bonded to the metal layer 41 through soldering. To this end, solder paste 43 is applied between the heat-conducting sheet 42 and the metal layer 41.

Herein, there are two methods that can be considered as a method for performing soldering of the heat-conducting sheet 42 to the metal layer 41. One of the soldering methods is the reflow soldering method, and the other is the induction-heating soldering method.

However, in the case of soldering by the reflow soldering method, since the molding part needs to withstand high temperatures, a material with high heat resistance needs to be used, and thermal damage may occur to the semiconductor chips and the like included in the semiconductor package during the soldering process. Therefore, therefore, in the present invention, it is more preferable to solder the heat-conducting sheet by the induction-heating method than by the reflow soldering method.

Meanwhile, since the induction-heating soldering locally heats only the conductor located within the magnetic field formed by the induction-heating coil, there is no need to use a material with high heat resistance for the molding part, and in particular, there is an advantage of no thermal damage to the semiconductor chips included in the semiconductor package. The method of bonding the metal layer to the heat-conducting sheet through induction-heating soldering will be described in more detail later. The heat-dissipating semiconductor package according to the present invention with the above-described configuration can directly transfer the heat generated from the semiconductor chip to the metal layer and the heat-conducting sheet through the engraved portion having the minimum thickness in the molding part and can dissipate the heat into the air, and the heat can also be dissipated to the outside through another external heat-dissipating member (TIM sheet or EMI shielding member). As described above, with respect to the heat-dissipating semiconductor package according to the present invention, metallization (metal layer) is formed in the molding part configuring the outer shape of the semiconductor package (MID: mold interconnected device), and the heat-conducting sheet is bonded to the metal layer by soldering. Accordingly, the heat-conducting member can be directly mounted in a state of being embedded inside the molding part made of a plastic material (MDM: molding direct mounting).

In this way, in the heat-dissipating semiconductor package according to the present invention, the heat-conducting member can be directly formed by applying MID and MDM to the plastic molding part configuring the outer shape thereof, so that three-dimensional heat dissipation and heat conduction can be implemented according to the three-dimensional shape of the semiconductor package, and thus, there is an advantage of being able to actively respond to the heat-dissipating portion according to the spatial environment in which the semiconductor package is installed.

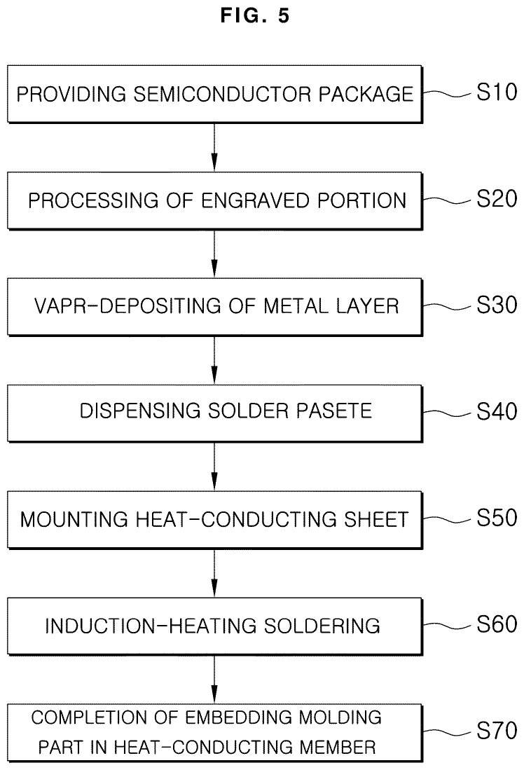

Hereinafter, a method for manufacturing a heat-dissipating semiconductor package in which a heat-conducting member is embedded according to an embodiment of the present invention will be described with reference to FIGS. 5 to 9.

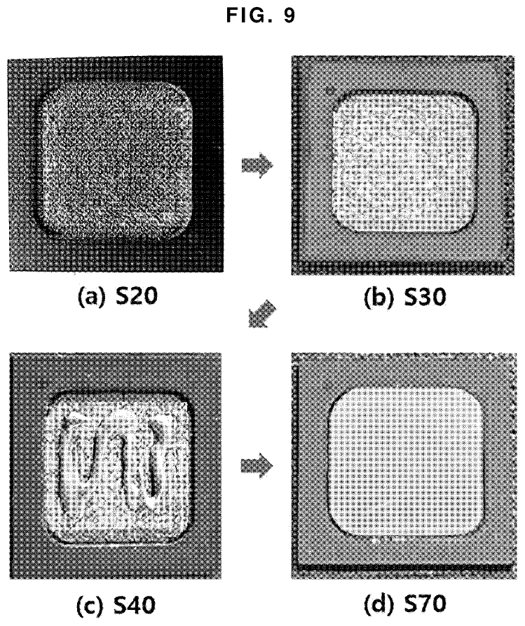

FIG. 5 is a flowchart illustrating a sequence of processes for manufacturing the heat-dissipating semiconductor package according to the embodiment of the present invention, FIGS. 6 to 8 are conceptual diagrams illustrating a sequence of processes for manufacturing the heat-dissipating semiconductor package according to the embodiment of the present invention, and FIG. 9 is a diagram illustrating a sequence of processes for manufacturing the heat-dissipating semiconductor package according to the embodiment of the present invention as an actual product.

First, the semiconductor package in which the semiconductor packaging process has been completed is provided (step S10 of FIG. 5, FIG. 6), and a certain area is removed by laser processing on the upper surface of the molding part 30 configuring the outer shape of the semiconductor packaging to form the engraved portion 31 (step S20 of FIG. 5, FIG. 6, FIG. 9(a)).

At this time, while the engraved portion 31 is formed by laser processing, a fine uneven pattern groove is formed on the bottom surface configuring the engraved portion 31. That is, the uneven surface 32 in the form of a diagonal or straight line with periodically repeated convex and concave patterns can be formed on the bottom surface of the engraved portion 31. A diode laser, an ultraviolet (UV) laser, an excimer laser, and the like can be used as the laser. In the present invention, various methods such as CNC (computerized numerical control) milling processing, wet etching, and dry etching can be applied to form the engraved portion, without being limited to laser processing.

After that, a metal layer 41 is vapor-deposited and formed by plating metal in the area of the engraved portion 31 (S30 of FIG. 5, FIG. 7, and (b) of FIG. 9). Herein, the metal layer 41 can be formed by stacking a first metal layer 41a including at least one of copper (Cu), nickel (Ni), aluminum (Al), titanium (Ti), and silicon (Si) on the uneven surface 32 forming the bottom surface of the engraved portion 31 and a second metal layer 41b including at least one of copper (Cu), nickel (Ni), and gold (Au) on the first metal layer. This metal layer 30 can selectively implement metallization on the area of the engraved portion by using wet plating using masking (100 in FIG. 7), PVD (physical vapor-deposition), CVD (chemical vapor-deposition), E-BEAM, and other dry thin film vapor-deposition methods.

Next, a heat-conducting sheet 42 is soldering-bonded on the metal layer 30 by using the induction-heating method to be directly mounted on the molding part.

To this end, the solder paste 43 is dispensed on the metal layer 41 (S40 of FIG. 5, FIG. 7, and (c) of FIG. 9). Then, a heat-conducting sheet 42 is mounted on the solder paste 43 (S50 of FIG. 5 and FIG. 8). Afterwards, an induction-heating unit 200 is disposed on the heat-conducting sheet 42 and induction-heated (S60 of FIG. 5 and FIG. 8), and by melting the solder paste 43, the heat-conducting sheet 42 can be embedded in the molding part 30 to a thickness (S70 of FIG. 5 and (d) of FIG. 9). At this time, the induction-heating unit 200 inductively heats the metal layer 41. Therefore, the solder paste 43 applied between the molding part 30 and the heat-conducting sheet 42 melts, and the heat-conducting sheet 42 can be directly mounted on the engraved portion 31 of the molding part 30 made of a plastic material. Herein, the induction-heating unit 200 is configured to include an induction-heating coil 210 electrically connected to a high-frequency power supply unit (not illustrated), and a magnetic core 220 disposed inside the induction-heating coil 210 to concentrate the magnetic flux induced by the induction-heating coil 210 to the soldering area. At this time, although the induction-heating unit 200 is not illustrated, induction-heating unit 200 can be moved in the X-axis/Y-axis/Z-axis directions through a transfer robot (not illustrated) to continuously perform soldering electronic components mounted on a plurality of circuit bricks. In addition, a transfer robot (not illustrated) is equipped with a plurality of induction-heating units so that a plurality of semiconductor packages can be soldered at the same time.

As described above, a heat-conducting sheet can be directly embedded in a molding part made of a plastic injection molding product by using local heating of magnetic induction type. Therefore, compared to a general reflow soldering method, the material of the molding part configuring the outer shape of the semiconductor package can be used without restrictions, and the heat-conducting sheet can be implemented in the molding part without thermal damage to components such as semiconductor chips mounted inside.

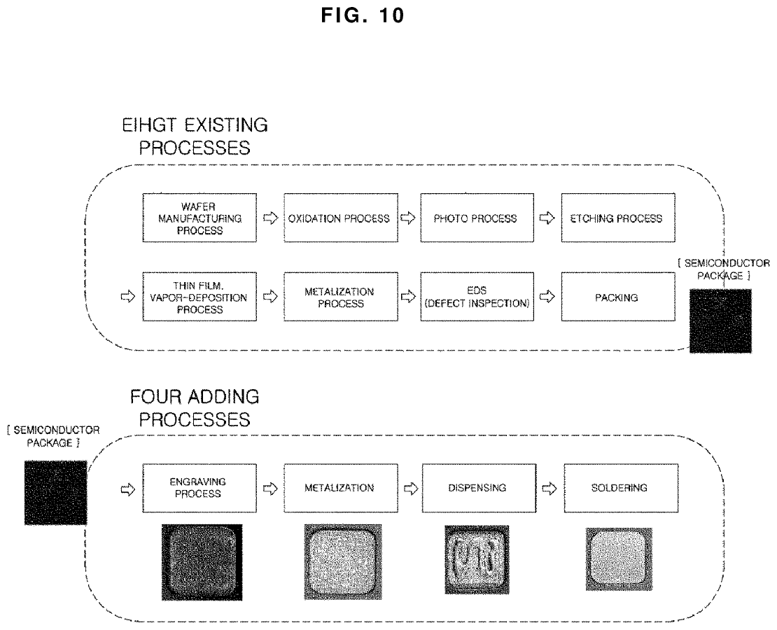

Meanwhile, as illustrated in FIG. 10, with respect to the heat-dissipating semiconductor package according to the present invention, a heat-conducting member is directly implemented in the molding part formed through a semiconductor packaging process, so that it can be additionally implemented inline after the eight manufacturing processes of the existing semiconductor package, and thus, the heat-dissipating semiconductor package according to the present invention is very advantageous in mass production and production line construction.

In addition, the induction-heating unit 200 used when manufacturing the heat-dissipating semiconductor package according to the present invention serves an induction-heating unit that can improve soldering quality by applying a cooling structure capable of cooling the heat of the magnetic core 220.

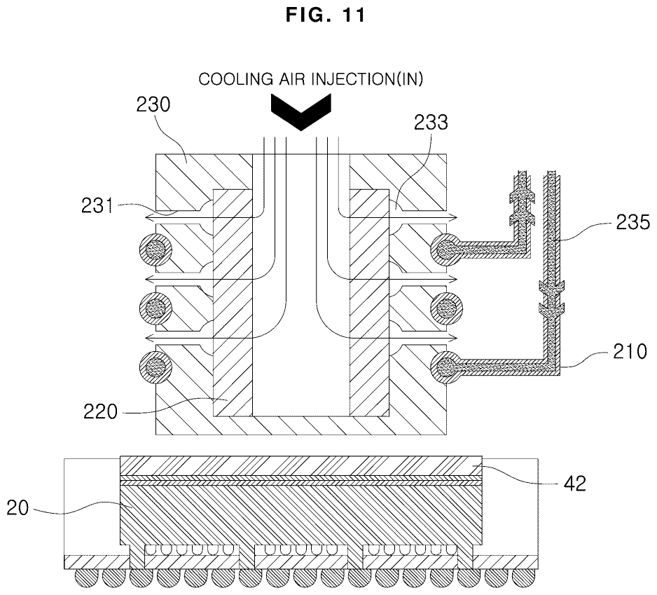

FIG. 11 is a conceptual diagram illustrating a side cooling air discharge type in an induction-heating unit applied to the heat-dissipating semiconductor package according to the embodiment of the present invention.

Referring to FIG. 11, the induction-heating unit 200 is configured to include an induction-heating coil 210, a magnetic core 220, and a coil bobbin 230.

The above-mentioned induction-heating coil 210 is electrically connected to a high-frequency power supply unit (not illustrated) to induce electromagnetic field, and a hollow copper tube with high electrical conductivity is used for the induction-heating coil.

The induction-heating coil 210 has a cooling water channel formed inside a hollow space to which cooling water 235 is supplied. Therefore, the heat generated from the magnetic core 220 can be quickly dissipated toward the induction-heating coil 210. Herein, the overall shape of the induction-heating coil 210 can be implemented in various shapes such as helical, square, and circular. Furthermore, depending on the type and the soldering environment of the semiconductor package, the induction-heating coil may be in the form of a very thin wire (for example, Litz wire) rather than a hollow tube shape.

The above-mentioned magnetic core 220 is located inside the induction-heating coil 210 and serves to concentrate the magnetic induction generated from the induction-heating coil 210. Herein, the magnetic core 220 can be configured in various shapes such as circular, square, and hollow.

The above-mentioned coil bobbin 230 serves as a housing in which the magnetic core 220 is inserted inside and the induction-heating coil 210 is placed outside. The coil bobbin 230 serves as a pressing plate that presses the heat-conducting sheet (32) so that it does not rise during soldering. A spiral groove may be formed on the outer surface of the coil bobbin 230 so that the induction-heating coil 210 can be fixed stably in the correct position. And a number of through-holes 231 serving as passages for the cooling air are formed on the side surface of the coil bobbin 230 at a certain distance from top to bottom. At this time, it is desirable that a flow hole 234 having a relatively wide diameter is formed on the inner surface of the coil bobbin 230 where the through-holes 231 are formed so that cooling air flowing in from the upper portion of the coil bobbin 230 can smoothly flow into the through-holes 231.

Meanwhile, the upper part of the coil bobbin 230 has an open structure so the cooling air can be flown into the upper part. Accordingly, the cooling air flowing into the upper part of the coil bobbin 230 can quickly dissipate the heat generated in the magnetic core 220 to the outside while passing through the magnetic core 220 and exiting through the through-holes 231. At this time, it is preferable to use a hollow shape in which the magnetic core 220 is open from top to bottom for effective heat exchange with the cooling air or a shape in which a hollow internal space can be maintained inside the coil bobbin 230.

In this way, the induction-heating unit 200 applied to the present invention can effectively concentrate a magnetic flux of the induction-heating coil 210 by cooling the magnetic core 220 using cooling air so that the magnetic core 220 is not heated to a high temperature, and thus, the soldering quality of the heat-conducting member in the semiconductor package is greatly improved.

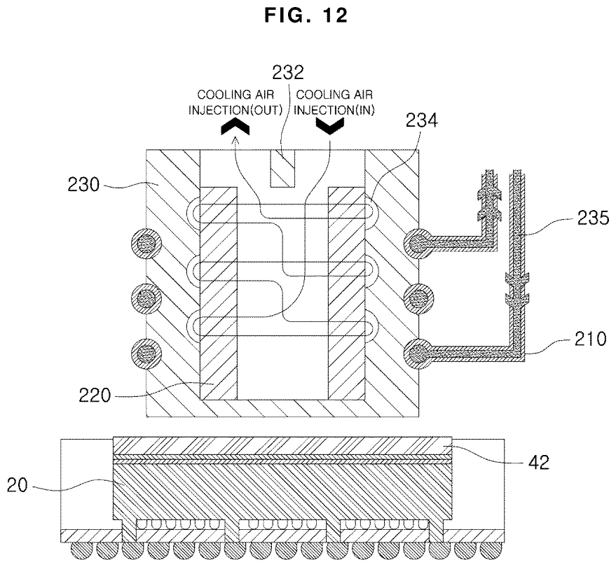

Meanwhile, in FIG. 12, other than FIG. 11, an upper cooling air discharge type as the cooling structure of the induction-heating unit is applied.

That is, instead of forming through-holes 231 with holes in the side surface of the coil bobbin 230, a completely closed structure is applied, and a partition wall 232 is formed in the open upper center of the coil bobbin 230. At this time, cooling air is injected to one side of the partition wall 232, and air that has completed heat exchange with the magnetic core 220 is discharged to the other side. To elaborate further, the air introduced to one side with the partition wall 232 as the center passes through the magnetic core 220 inserted inside the coil bobbin 230 and escapes through the opening on the opposite side where the air introduced with the partition wall 232 as the center, and thus, a flow of the air dissipates the heat generated in the magnetic core 220 to the outside. At this time, a number of flow grooves 234 in the form of grooves that are concave inward are formed at a certain interval from top to bottom on the inner surface of the coil bobbin 230 being in contact with the magnetic core 220.

Accordingly, sufficient heat exchange with the cooling air is performed not only on the inner side of the magnetic core 220 but also on the outer side of the magnetic core 220, so that the cooling efficiency of the magnetic core can be improved.

Although each embodiment of the present invention has been described above with reference to the drawings, those skilled in the art will understand that the present invention can be variously modified and changed within the scope that does not depart from that the scope and spirit of the present invention described in the following patent claims.

And the semiconductor package according to the present invention can be widely used in many industrial fields for all kinds of purposes such as smart phones, tablets, wearables, digital cameras, and wireless routers.

### INDUSTRIAL APPLICABILITY

The present invention relates to a heat-dissipating semiconductor package with an embedded heat-conducting member, a manufacturing method thereof, and an induction-heating soldering device used in the manufacturing thereof, and the present invention can be widely used in the semiconductor manufacturing industry, an electronic device manufacturing industry such as smart phones, tablets, wearables, digital cameras, wireless routers, and the like, and an Al industry.

1. A heat-dissipating semiconductor package with an embedded heat-conducting member comprising:
a board;
a semiconductor chip mounted on the board;
a molding part surrounding a side surface of the semiconductor chip on the board; and
the heat-conducting member formed on the molding part and dissipating heat generated from the semiconductor chip to an outside of the molding part.

2. The heat-dissipating semiconductor package with the embedded heat-conducting member according to claim 1, wherein the heat-conducting member includes:
a metal layer vapor-deposition-formed on at least one surface of the molding part;
solder paste applied on the metal layer; and
a heat-conducting sheet soldering-bonded to the metal layer by the solder paste.

3. A heat-dissipating semiconductor package with an embedded heat-conducting member comprising:
a board;
a semiconductor chip mounted on the board;
a molding part surrounding a side surface of the semiconductor chip on the board; and
a heat-conducting member embedded in the molding part and dissipating heat generated from the semiconductor chip to the outside of the molding part.

4. The heat-dissipating semiconductor package with the embedded heat-conducting member according to claim 3, wherein an engraved portion is formed with a predetermined thickness on at least one side of the molding part, and
wherein the heat-conducting member includes a heat-conducting sheet bonded to an inside of the engraved portion and dissipating heat generated from the semiconductor chip to the outside.

5. The heat-dissipating semiconductor package with the embedded heat-conducting member according to claim 4, wherein an uneven surface with a plurality of uneven portions is formed on the bottom surface of the engraved portion, and
wherein the heat-conducting member further includes a metal layer vapor-deposition-formed on the uneven surface and solder paste applied on the metal layer, so that the heat-conducting sheet is soldering-bonded to the metal layer.

6. The heat-dissipating semiconductor package with the embedded heat-conducting member according to claim 2, wherein metal layer includes:
a first metal layer formed on the uneven surface and including at least one of copper (Cu), nickel (Ni), aluminum (Al), titanium (Ti), and silicon (Si); and
a second metal layer formed on the first metal layer and including at least one of copper (Cu), nickel (Ni), and gold (Au).

7. The heat-dissipating semiconductor package with the embedded heat-conducting member according to claim 1, wherein the heat-conducting sheet is made of a material having a higher thermal conductivity than a material configuring the molding part.

8. The heat-dissipating semiconductor package with the embedded heat-conducting member according to claim 7, wherein the heat-conducting sheet is made of metal, carbon fiber, graphite, or ceramic.

9. A method for manufacturing a heat-dissipating semiconductor package with an embedded heat-conducting member, comprising:
providing a semiconductor package in which a packaging process of a semiconductor chip is completed;
forming an engraved portion with an uneven surface formed on at least one surface of a molding part configuring an outer shape of the semiconductor package by laser processing;
vapor-depositing a metal layer on the concave surface by plating;
dispensing solder paste on the metal layer;
mounting a heat-conducting sheet on the solder paste; and
melting the solder paste by heating the solder paste.

10. The method for manufacturing the heat-dissipating semiconductor package with the embedded heat-conducting member, according to claim 9, further comprising:
disposing an induction-heating member adjacent to the heat-conducting sheet for a heating method for melting the solder paste using induction-heating soldering; and
melting the solder paste in the induction-heating unit so that the heat-conducting sheet is substantially directly mounted in the molding part.

11. (canceled)
